(19) United States
(12) Patent Application Publication
(10) Pub. No.: US 2009/0263678 A1
(43) Pub. Date: Oct. 22, 2009

(54) METAL MATERIAL WITH ELECTRIC CONTACT LAYER AND MANUFACTURING METHOD OF THE SAME

(75) Inventors: Takaaki SASAOKA, Tsuchiura-shi (JP); Mineo WASHIMA, Tsuchiura-shi (JP); Masahiro SEIDOU, Tsuchiura-shi (JP)

Correspondence Address: Fleit Gibbons Gutman Bongini & Bianco PL, 21355 EAST DIXIE HIGHWAY, SUITE 115, MIAMI, FL, 33180, US

(73) Assignee: HITACHI CABLE, LTD., Tokyo (JP)

(21) Appl. No.: 12/415,043

(22) Filed: Mar. 31, 2009

(30) Foreign Application Priority Data
Apr. 16, 2008 (JP) 2008-107137

(51) Int. Cl. B32B 15/01; B32B 15/00; B05D 5/12; C23C 14/34

(52) U.S. Cl. 428/669; 428/655; 427/124; 427/528; 204/192.12

(57) ABSTRACT

A metal material with electric contact layer includes a metal base made of metal containing chromium; an adhesive layer formed on a surface of the metal base, mainly containing chromium and having a thickness of 5 nm or more and 200 nm or less; and an electric contact layer formed on the surface of the adhesive layer, made of noble metal or an alloy of the noble metal, and having a thickness of 1 nm or more and 20 nm or less.

### BACKGROUND

1. Technical Field

The present invention relates to a metal material with electric contact layer in which the electric contact layer made of noble metal or an alloy of the noble metal is added to a metal base made of metal containing chromium, and a manufacturing method of the same.

2. Description of Related Art

Conventionally, a metal material with electric contact layer having the electric contact layer on a surface of the metal material is used, for example, in an electrode material of a battery and an electric contact part of a connector. Noble metal such as Au(gold), Pt (platinum), and Sn (tin), Ni (nickel) are given as typical metal used as a forming material of the electric contact layer. The electric contact layer is formed by providing such metal, for example, on the surface of the metal material (metal base) such as a metal thin plate or a metal foil, by plating, etc.

In order to further increase reliability and durability of the electric contact layer, the noble metal such as Au having chemically stable characteristics is more preferably used than Sn and Ni, etc.

However, when the noble metal such as Au is used, for example, in a step of applying gold plating as the electric contact layer, on the surface of the metal on which a passivation film such as stainless steel containing, for example, Cr (chromium) is formed, a manufacturing cost is increased, due to the fact that complicated pre-processing is required, and noble metal plating must be made thick to maintain the durability. In addition, generally the noble metal is hardly available and a material cost is higher than that of other metal. Therefore, comprehensively, the metal material with electric contact layer incurs high cost.

Also, in order to surely form the electric contact layer made of noble metal on the surface of the metal base on which the passivation film such as stainless steel is formed, and in order to prevent peel-off of this electric contact layer after formation, various techniques such as forming a so-called underlying layer under the electric contact layer, are proposed and some of them are put to practical use.

Ni, Sn, Ag (silver) can be considered as the metal for forming such an underlying layer.

Patent document 1 proposes a technique of forming an Ag layer and Ni or Co (cobalt) layer as the underlying layer, and forming the electric contact layer made of Pd(palladium) thereon.

Patent document 2 proposes a technique of forming the electric contact layer made of Pd—Ni alloy on the underlying layer made of Ni.

Patent document 3 proposes the underlying layer made of Sn plating.

According to the aforementioned patent documents 1 to 3, although Ni, Sn, Co, etc, are used as the underlying layer, in a case of Ni, for example, when the underlying layer itself made of Ni is used in the circumstance such as allowing electrochemical corrosion to occur, there is a possibility that durability is deteriorated. In addition, in the metal material with electric contact layer having the underlying layer by plating, when press-molding is applied after plating, this plated layer is peeled off in many cases during this press-molding or after press-molding, and therefore the press-molding after plating is actually difficult.

Also, patent document 4 proposes a technique of forming the electric contact layer on a titanium metal plate by Au plating without the underlying layer. However, in this technique, the durability of the electric contact layer is hardly ensured, and the press-molding after plating is also difficult.

Patent document 5 proposes a separator for a fuel cell in which the underlying layer made of metal selected from any one of Ti (titanium), Ni, Ta(tantalum), Nb(niobium), Pt is formed, and a noble metal layer is formed on the surface of this underlying layer.

Also, patent document 6 proposes a technique of forming a metal layer of Pd(palladium) on a Ti layer, and a joint part of the Ti layer and the Pd layer is subjected to alloying treatment by heating this part. This separator for the fuel cell aims to improve the durability.

(Patent document 1) Japanese Patent No. 3956841

(Patent document 2) Japanese Patent No. 3161805

(Patent document 3) Japanese Patent Laid Open Publication No. 2007-9304

(Patent document 4) Japanese Patent Laid Open Publication No. 2007-146250

(Patent document 5) Japanese Patent Laid Open Publication No. 2007-146250

(Patent document 6) International Patent Publication No. (WO)2006/126613 A1

However, according to the aforementioned conventionally proposed techniques, it is not taken into consideration to achieve both of the reduction of a use amount of the noble metal, being a forming material of the electric contact layer; and press-molding work applied to the electric contact layer after forming this layer without posing a problem such as peel-off of the electric contact layer, in the metal material with electric contact layer wherein the electric contact layer of noble metal is formed on the surface of the metal base made of metal containing chromium.

Also, even if the conventional technique including the aforementioned proposals is individually used, or even if these techniques are used by combining with one another, it is impossible to realize the metal material with electric contact layer possible to reduce the use amount of the noble metal, being a main forming material of the electric contact layer, and possible to apply the press-molding without being peeled-off of the electric contact layer.

Also, a surface layer of chrome oxide, being a passivation film, is generated on the surface of the metal base made of metal containing chromium, and therefore it is difficult to thinly and firmly form the electric contact layer made of noble metal on this surface, without complicated surface and taking a lot of time for film formation.

### SUMMARY OF THE INVENTION

An object of the present invention is to provide a metal material with electric contact layer and a manufacturing method of the same, capable of reducing a use amount of a noble metal, being a material of an electric contact layer, and form a firm electric contact layer, in the metal material with electric contact layer having the electric contact layer made of the noble metal or the alloy of the noble metal on the surface of a metal base made of metal containing chromium.

One of the aspects of the present invention provides the metal material with electric contact layer including a metal base made of metal containing chromium; an adhesive layer formed on the surface of the metal material, made of metal mainly containing chromium, and having a thickness of 5 nm or more and 200 nm or less; and an electric contact layer formed on the surface of the adhesive layer, made of a noble metal or the alloy of the noble metal, and having a thickness of 1 nm or more and 20 nm or less.

Another aspect of the present invention provides a manufacturing method of a metal material with electric contact layer, including the steps of:

forming an adhesive layer made of metal mainly containing chromium on the surface of a metal base made of metal containing chromium so as to have a thickness of 5 nm or more and 200 nm or less by a vapor-phase method in a chamber; and

forming the electric contact layer made of noble metal or an alloy of the noble metal, on the surface of this adhesive layer subsequent to formation of the adhesive layer in the chamber, so as to have a thickness of 1 nm or more and 20 nm or less by a vapor-phase method.

### BRIEF DESCRIPTION OF THE DRAWINGS

FIG. 1 is a sectional view showing a structure of a main essential part of a metal material with electric contact layer according to an embodiment of the present invention.

FIG. 2A is a plan view schematically showing a molded product obtained by applying press-molding work to a thin plate-shaped metal material with electric contact layer according to examples and comparative examples of the present invention.

FIG. 2B is an expanded sectional view of FIG. 2A taken along the line B-B.

FIG. 3 is a schematic configuration diagram explaining a measurement method of a contact resistant value in the molded product of the metal material with electric contact layer manufactured as the examples and the comparative examples.

### DESCRIPTION OF PREFERRED EMBODIMENTS OF THE INVENTION

A metal material with electric contact layer and a manufacturing method of the same according to preferred embodiments of the present invention will be described hereunder, with reference to the drawings.

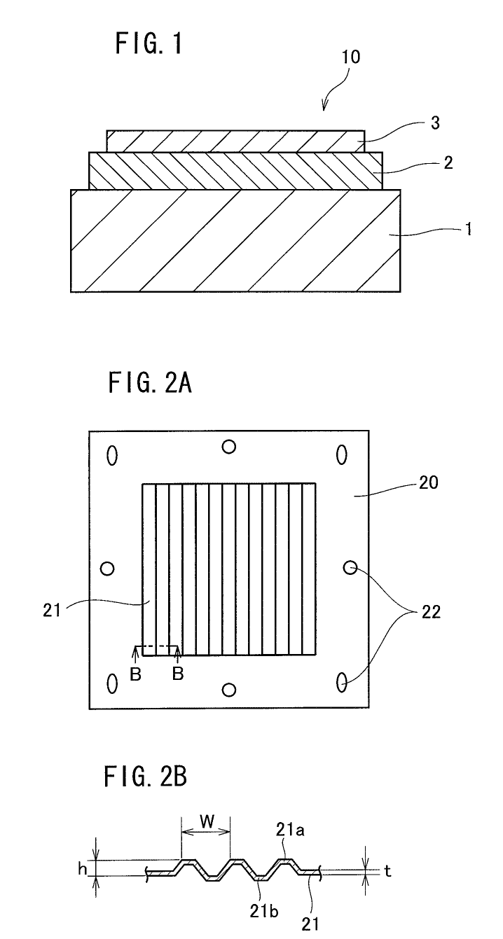

FIG. 1 is a sectional view showing a structure of a main essential part of the metal material with electric contact layer according to an embodiment of the present invention.

A metal material with electric contact layer 10 includes: a metal base 1 made of metal containing Cr (chromium); an adhesive layer 2 formed on the surface of this metal base 1, made of metal mainly containing Cr, or made of metal mainly containing chromium and further containing nickel or cobalt, and having a thickness of 5 nm or more and 200 nm or less; and an electric contact layer 3 further formed on the surface of the adhesive layer 2, made of noble metal selected from any one of, for example, Au(gold), Pt (platinum), Rh(rhodium) Ru(ruthenium), Ir(iridium), Ag(silver), and Pd(palladium), or made of an alloy of the noble metal containing at least one kind of them, and having a thickness of 1 nm or more and 20 nm or less. The adhesive layer 2 is formed on the whole part or a part of the surface of the metal base 1. Also, the electric contact layer 3 is formed on the whole part or a part of the surface of the adhesive layer 2.

As a main manufacturing step of the metal material with electric contact layer 10, first, the adhesive layer 2 made of metal mainly containing Cr is formed on the surface of the metal base 1 made of metal containing Cr by a vapor-phase method in a prescribed chamber that can be air-tightly closed in a vacuum state, so as to have a thickness of 5 nm or more and 200 nm or less. Then, in the same chamber as the aforementioned chamber, subsequent to the formation of the adhesive layer 2, the electric contact layer 3 made of the noble metal selected from, for example, any one of Au, Pt, Rh, Ru, Ir, Ag, Pd, or made of the alloy of the noble metal containing at least one kind of them, is formed so as to have a thickness of 1 nm or more and 20 nm or less. Thus, a main essential part of the metal material with electric contact layer 10 according to an embodiment of the present invention is manufactured.

Invar (Fe—Co—Cr alloy, Fe—Ni alloy, Fe—Ni—Co alloy), Austenitic stainless steel (such as SUS304 (Fe—Cr—Ni alloy) defined in JIS (Japanese Industrial Standards) G4305, SUS316 (Fe—Cr—Ni—Mo alloy) defined in JIS G4305), Ferritic stainless steel (such as SUS430 (Fe—Cr alloy) etc, defined in JIS G4305), Kovar (trade mark, Fe—Ni—Co alloy), Permalloy(Fe—Ni alloy), Hastelloy (trade mark, Ni—Mo—Fe—Co alloy), Inconel (trade mark, Ni—Fe—Cr—Nb—Mo alloy), etc, can be suitably used as specific examples of materials of the metal base 1 made of metal containing Cr. Alternately, the material of the metal base 1 is not limited to the metal material of a single structure of metal as described above, and can be used as a composite metal material in which a metal foil or a metal thin plate made of metal containing Cr is cladded on the surface of the metal material (which may be the material containing Cr or not containing Cr).

The adhesive layer 2 and the electric contact layer 3 are formed on the surface of the metal base 1 in this order. Preferably, formation of the adhesive layer 2 and the electric contact layer 3 is continuously performed in the same vacuum chamber. A physical vapor deposition (such as sputtering, vacuum deposition, ion beam deposition, and ion plating) or a chemical vapor deposition (such as thermal CVD, plasma CVD, and optical CVD) is used as the vapor-phase method (vapor-phase film deposition method, vapor growth method).

First, the adhesive layer 2 is formed on the surface of the metal base 1. This adhesive layer 2 is provided as an underlying layer of the electric contact layer 3, for firmly joining the electric contact layer 3 to the metal base 1 without increasing a contact resistance on a surface layer of the metal base 1. Preferably, firm joint by the adhesive layer 2 is performed so as not to allow peel-off of the electric contact layer 3 to occur during press working or after press working, even if the press working is performed after the electric contact layer 3 is formed.

The metal mainly containing Cr, or the metal mainly containing Cr and further containing Ni or Co is used as the forming material of the adhesive layer 2. As a further specific aspect, the adhesive layer 2 made of, for example, Cr—Ni alloy is preferably used.

Then, the thickness of the adhesive layer 2 (average thickness more specifically) is set at 5 nm or more and 200 nm or less. A secure and firm joint as described above is achieved without increasing the contact resistance, by setting the thickness of the adhesive layer 2 in a range of 5 nm to 200 nm. This is because when the thickness of the adhesive layer 2 is under 5 nm, the contact resistance is increased, and when the thickness exceeds 200 nm, mechanical peel-off of the adhesive layer 2 from the metal base 1 is easily generated.

There are mainly two reasons for forming the adhesive layer 2 by the metal mainly containing Cr.

A first reason is that since the metal base 1 is made of metal containing Cr, generally the chrome oxide is formed on its surface layer, but by making the adhesive layer 2 also made of metal mainly containing Cr, adhesion (or tight contact or joint performance) between the adhesive layer 2 and the surface of the metal base 1 becomes excellent.

A second reason is that since the metal itself such as Cr is a corrosion resistant material of a type forming the passivation film on the surface, chemical stability of the adhesive layer 2 itself can be ensured by forming the adhesive layer 2, with Cr as its main component.

In addition, as a further specific aspect, preferably the adhesive layer 2 is made of the metal mainly containing Cr and further containing Ni or Co. This is because further improvement of a heat resistance property and a mechanical stretching amount of the adhesive layer 2 itself can be achieved by making the adhesive layer 2 containing Cr and further containing Ni or Co. Namely, in a case of the Cr as a single substance, there is a possibility that the heat resistant property is insufficient in some cases. However, by making a Cr—Ni alloy and a Cr—Co alloy by adding Ni or Co, the heat resistant property is remarkably improved and the stretching amount, being mechanical characteristics, is also improved.

Next, the electric contact layer 3 is formed on the surface of the adhesive layer 2. The electric contact layer 3 is provided for decreasing the contact resistance of the metal material with electric contact layer 10 and ensuring the durability of an electric contact part. In order to respond to such a request, the noble metal such as Au, Pt, Rh, Ru, Ir, Ag, Pd, or the alloy of the noble metal containing at least one kind of them, is preferably used, as the forming material of the electric contact layer 3.

The thickness of the electric contact layer 3 is set at 1 nm or more and 20 nm or less. This makes it possible to reduce mechanical internal strain by making the electric contact layer 3 thin, such as 20 nm or less, and the durability for performing press-molding can be obtained without posing a problem such as peel-off of the electric contact layer. However, when the thickness of the electric contact layer 3 is excessively thin, such as under 1 nm, oxide layer is formed on the surface of the adhesive layer 2, which is the layer under the electric contact layer 3, and by a long time use, the thickness of the oxide layer becomes 1 nm or more, and there is a high possibility that the contact resistance is increased. Also, when the electric contact layer 3 has a thickness exceeding 20 nm, the mechanical internal strain becomes great, thus easily allowing the peel-off of the electric contact layer 3 to occur from the metal base 1. Therefore, by setting the thickness of the electric contact layer 3 at 1 nm or more and 20 nm or less, the contact resistance can be reduced and the durability of the electric contact part can be ensured.

Namely, an experiment and consideration are performed for various kinds of samples with different thickness and materials as will be described in detail in the example described hereunder. As a result it is found that by forming the adhesive layer 2 and the electric contact layer 3 having the aforementioned material and thickness, on the surface of the metal base 1 in this order, it is possible to realize excellent durability not causing the peel-off of the electric contact layer 3 or not causing deterioration of the durability even if the press-molding work is applied to the electric contact layer 3 after forming this layer, and also it is possible to realize reduction of the use amount of noble metal. Thus, the present invention is achieved.

According to the metal material with electric contact layer 10 and the manufacturing method of the same according to an embodiment of the present invention, it is possible to realize the reduction of the use amount of the noble metal such as Au and Pt, being the forming material of the electric contact layer 3, and also it is possible to realize a firm joint thereby allowing the press-molding work to be performed without posing the problem such as peel-off of the electric contact layer 3. Consequently it is possible to realize reduction of total cost of the metal material with electric contact layer 10 and improvement of the durability of the electric contact layer 3 after press work.

Note that although the above-described embodiment describes a case that the press-molding work is applied to the metal base 1 after the adhesive layer 2 and the electric contact layer 3 are formed, of course it is also possible to form the adhesive layer 2 and the electric contact layer 3 on the surface of the metal base 1 after the press-molding work is applied to the metal base 1. In this case also, it is possible to realize both of the reduction of the total cost of the metal material with electric contact layer 10 and further improvement of the durability of the electric contact layer 3.

In the forming method of the adhesive layer 2 and the electric contact layer 3, it is preferable to use the vapor phase method such as the aforementioned sputtering, vacuum deposition, and CVD. However, the present invention is not limited to the film deposition method by the vapor phase method.

Also, in order to achieve further improvement of the durability of the electric contact layer 3 and the contact layer 2, it is also acceptable to perform oxidation process and anodizing, for the purpose of sealing pin holes, after the electric contact layer 3 is formed.

### EXAMPLES

Various plate materials of the metal material with electric contact layer having the specification as described above in the aforementioned embodiment were manufactured, and by applying press-molding work to these plate materials, samples of molded product 20 made of the metal material with electric contact layer according to examples were manufactured (FIG. 2A and FIG. 2B). In addition, various plate materials of the metal material with electric contact layer having the specification different from those described in the aforementioned embodiment were manufactured, and by applying the press-molding work to these plate materials, the samples of the molded product 20 made of the metal material with electric contact layer according to comparative examples were manufactured (FIG. 2A, FIG. 2B). Then, the contact resistance and the durability of each of the samples of the examples and the comparative examples were evaluated respectively.

Table 1 collectively shows main essential specifications and evaluation results of each sample of examples 1 to 21, and each sample of comparative examples 1 to 6. Similarly, table 2 collectively shows main essential specifications and evaluation results of each sample of examples 22 to 35, and table 3 collectively shows main essential specifications and evaluation results of each sample of examples 36 to 59, and table 4 collectively shows main essential specifications and evaluation results of each sample of examples 60 to 83.

TABLE 1

| | | | | Electric contact | | Contact resistance | | |
|---|---|---|---|---|---|---|---|---|
| | | Adhesive layer | | layer | | (mΩcm²) | | Surface state |
| | | material | Thickness | material | Thickness | Initial | After environment | after environment |
| Sample | Metal base | kind | (nm) | kind | (nm) | value | test | test |
| Example 1 | SUS430 | Cr | 10.0 | Au | 1.0 | 8 | 24 | No chage |
| Example 2 | SUS430 | Cr | 10.0 | Au | 10.0 | 7 | 21 | No chage |
| Example 3 | SUS430 | Cr | 10.0 | Au | 20.0 | 7 | 21 | No chage |
| Example 4 | SUS430 | Cr | 5.0 | Au | 10.0 | 7 | 22 | No chage |
| Example 5 | SUS430 | Cr | 50.0 | Au | 10.0 | 7 | 22 | No chage |
| Example 6 | SUS430 | Cr | 100.0 | Au | 10.0 | 7 | 24 | No chage |
| Example 7 | SUS430 | Cr | 150.0 | Au | 10.0 | 7 | 24 | No chage |
| Example 8 | SUS430 | Cr | 200.0 | Au | 10.0 | 7 | 24 | No chage |
| Example 9 | SUS430 | Cr | 10.0 | Pt | 1.0 | 8 | 23 | No chage |
| Example 10 | SUS430 | Cr | 10.0 | Pt | 20.0 | 7 | 22 | No chage |
| Example 11 | SUS430 | Cr | 10.0 | Ru | 1.0 | 8 | 22 | No chage |
| Example 12 | SUS430 | Cr | 10.0 | Ru | 20.0 | 7 | 21 | No chage |
| Example 13 | SUS430 | Cr | 10.0 | Ir | 1.0 | 8 | 24 | No chage |
| Example 14 | SUS430 | Cr | 10.0 | Ir | 20.0 | 7 | 22 | No chage |
| Example 15 | SUS430 | Cr | 10.0 | Rh | 1.0 | 8 | 24 | No chage |
| Example 16 | SUS430 | Cr | 10.0 | Rh | 20.0 | 7 | 22 | No chage |
| Example 17 | SUS430 | Cr | 10.0 | Ag | 1.0 | 8 | 24 | No chage |
| Example 18 | SUS430 | Cr | 10.0 | Ag | 20.0 | 7 | 22 | No chage |
| Example 19 | SUS430 | Cr | 10.0 | Pd | 1.0 | 8 | 24 | No chage |
| Example 20 | SUS430 | Cr | 10.0 | Pd | 20.0 | 7 | 22 | No chage |
| Example 21 | SUS430 | Cr | 10.0 | Pd | 20.0 | 7 | 22 | No chage |
| Comparative | SUS430 | — | 0 | Au | 15 | 9 | 32 | No chage |
| example 1 | | | | | | | | |
| Comparative | SUS430 | Cr | 10.0 | Au | 0.5 | 12 | 30 | No chage |
| example 2 | | | | | | | | |
| Comparative | SUS430 | Cr | 10.0 | Au | 25.0 | 7 | 30 | No chage |
| example 3 | | | | | | | | |
| Comparative | SUS430 | Cr | 250.0 | Au | 10.0 | 7 | 44 | Peel-off |
| example 4 | | | | | | | | |
| Comparative | SUS430 | Cr | 10.0 | Pt | 0.5 | 12 | 30 | No chage |
| example 5 | | | | | | | | |
| Comparative | SUS430 | Cr | 10.0 | Pt | 25.0 | 7 | 35 | No chage |
| example 6 | | | | | | | | |

TABLE 2

| | | | | Electric contact | | Contact resistance | | |
|---|---|---|---|---|---|---|---|---|
| | | Adhesive layer | | layer | | (mΩcm²) | | Surface state |
| | Metal | material | Thickness | material | Thickness | Initial | After environment | after environment |
| Sample | base | kind | (nm) | kind | (nm) | value | test | test |
| Example 22 | SUS304 | Cr | 10.0 | Au | 1 | 8 | 23 | No chage |
| Example 23 | SUS316 | Cr | 10.0 | Au | 1 | 8 | 23 | No chage |
| Example 24 | Kovar | Cr | 10.0 | Au | 1 | 8 | 23 | No chage |
| Example 25 | Permalloy | Cr | 10.0 | Au | 1 | 8 | 23 | No chage |
| Example 26 | Hastelloy | Cr | 10.0 | Au | 1 | 8 | 23 | No chage |
| Example 27 | Invar | Cr | 10.0 | Au | 1 | 8 | 23 | No chage |
| Example 28 | Inconel | Cr | 10.0 | Au | 1 | 8 | 23 | No chage |
| Example 29 | SUS304 | Cr | 10.0 | Au | 20.0 | 7 | 21 | No chage |
| Example 30 | SUS316 | Cr | 10.0 | Au | 20.0 | 7 | 21 | No chage |
| Example 31 | Kovar | Cr | 10.0 | Au | 20.0 | 7 | 21 | No chage |
| Example 32 | Permalloy | Cr | 10.0 | Au | 20.0 | 7 | 21 | No chage |
| Example 33 | Hastelloy | Cr | 10.0 | Au | 20.0 | 7 | 21 | No chage |
| Example 34 | Invar | Cr | 10.0 | Au | 20.0 | 7 | 21 | No chage |
| Example 35 | Inconel | Cr | 10.0 | Au | 20.0 | 7 | 23 | No chage |

TABLE 3

| | | Adhesive layer | | | | | | |
|---|---|---|---|---|---|---|---|---|
| | | Metal excluding | | | | | | |
| | | Cr is added | | | | | | |
| | | (Addition | | | | | | |
| | | Concentration | | Electric | | Contact resistance | | |
| | | wt %) | | contact layer | | (mΩcm²) | | Surface state |
| | Metal | material | Thickness | material | Thickness | Initial | After environment | after environment |
| Sample | base | kind | (nm) | kind | (nm) | value | test | test |
| Example 36 | SUS304 | Cr—16Ni | 10.0 | Au | 1 | 8 | 23 | No chage |
| Example 37 | SUS316 | Cr—16Ni | 10.0 | Au | 1 | 8 | 23 | No chage |
| Example 38 | SUS430 | Cr—16Ni | 10.0 | Au | 1 | 8 | 23 | No chage |
| Example 39 | Kovar | Cr—16Ni | 10.0 | Au | 1 | 8 | 23 | No chage |
| Example 40 | Permalloy | Cr—16Ni | 10.0 | Au | 1 | 8 | 23 | No chage |
| Example 41 | Hastelloy | Cr—16Ni | 10.0 | Au | 1 | 8 | 23 | No chage |
| Example 42 | Invar | Cr—16Ni | 10.0 | Au | 1 | 8 | 23 | No chage |
| Example 43 | Inconel | Cr—16Ni | 10.0 | Au | 1 | 8 | 23 | No chage |
| Example 44 | SUS304 | Cr—16Ni | 10.0 | Au | 20.0 | 7 | 21 | No chage |
| Example 45 | SUS316 | Cr—16Ni | 10.0 | Au | 20.0 | 7 | 21 | No chage |
| Example 46 | SUS430 | Cr—16Ni | 10.0 | Au | 20.0 | 7 | 21 | No chage |
| Example 47 | Kovar | Cr—16Ni | 10.0 | Au | 20.0 | 7 | 21 | No chage |
| Example 48 | Permalloy | Cr—16Ni | 10.0 | Au | 20.0 | 7 | 21 | No chage |
| Example 49 | Hastelloy | Cr—16Ni | 10.0 | Au | 20.0 | 7 | 21 | No chage |
| Example 50 | Invar | Cr—16Ni | 10.0 | Au | 20.0 | 7 | 21 | No chage |
| Example 51 | Inconel | Cr—16Ni | 10.0 | Au | 20.0 | 7 | 23 | No chage |
| Example 52 | SUS304 | Cr—16Co | 10.0 | Au | 20.0 | 7 | 21 | No chage |
| Example 53 | SUS316 | Cr—16Co | 10.0 | Au | 20.0 | 7 | 21 | No chage |
| Example 54 | SUS430 | Cr—16Co | 10.0 | Au | 20.0 | 7 | 21 | No chage |
| Example 55 | Kovar | Cr—16Co | 10.0 | Au | 20.0 | 7 | 21 | No chage |
| Example 56 | Permalloy | Cr—16Co | 10.0 | Au | 20.0 | 7 | 21 | No chage |
| Example 57 | Hastelloy | Cr—16Co | 10.0 | Au | 20.0 | 7 | 21 | No chage |
| Example 58 | Invar | Cr—16Co | 10.0 | Au | 20.0 | 7 | 21 | No chage |
| Example 59 | Inconel | Cr—16Co | 10.0 | Au | 20.0 | 7 | 23 | No chage |

TABLE 4

| | | | | Electric contact | | Contact resistance | | |
|---|---|---|---|---|---|---|---|---|
| | | Adhesive layer | | layer | | (mΩcm²) | | Surface state |
| | Metal | material | Thickness | material | Thickness | Initial | After environment | after environment |
| Sample | base | kind | (nm) | kind | (nm) | value | test | test |
| Example 60 | SUS304 | Cr | 10.0 | Pd—10 wt % Au | 1 | 8 | 23 | No chage |
| Example 61 | SUS316 | Cr | 10.0 | Pd—10 wt % Au | 1 | 8 | 23 | No chage |
| Example 62 | SUS430 | Cr | 10.0 | Pd—10 wt % Au | 1 | 8 | 23 | No chage |
| Example 63 | Kovar | Cr | 10.0 | Pd—10 wt % Au | 1 | 8 | 23 | No chage |
| Example 64 | Permalloy | Cr | 10.0 | Pd—10 wt % Au | 1 | 8 | 23 | No chage |
| Example 65 | Hastelloy | Cr | 10.0 | Pd—10 wt % Au | 1 | 8 | 23 | No chage |
| Example 66 | Invar | Cr | 10.0 | Pd—10 wt % Au | 1 | 8 | 23 | No chage |
| Example 67 | Inconel | Cr | 10.0 | Pd—10 wt % Au | 1 | 8 | 23 | No chage |
| Example 68 | SUS304 | Cr | 10.0 | Ag—10 wt % Pd | 20.0 | 7 | 21 | No chage |
| Example 69 | SUS316 | Cr | 10.0 | Ag—10 wt % Pd | 20.0 | 7 | 21 | No chage |
| Example 70 | SUS430 | Cr | 10.0 | Ag—10 wt % Pd | 20.0 | 7 | 21 | No chage |
| Example 71 | Kovar | Cr | 10.0 | Ag—10 wt % Pd | 20.0 | 7 | 21 | No chage |
| Example 72 | Permalloy | Cr | 10.0 | Ag—10 wt % Pd | 20.0 | 7 | 21 | No chage |
| Example 73 | Hastelloy | Cr | 10.0 | Ag—10 wt % Pd | 20.0 | 7 | 21 | No chage |
| Example 74 | Invar | Cr | 10.0 | Ag—10 wt % Pd | 20.0 | 7 | 21 | No chage |
| Example 75 | Inconel | Cr | 10.0 | Ag—10 wt % Pd | 20.0 | 7 | 23 | No chage |
| Example 76 | SUS304 | Cr | 10.0 | Ag—10 wt % Au | 20.0 | 7 | 21 | No chage |
| Example 77 | SUS316 | Cr | 10.0 | Ag—10 wt % Au | 20.0 | 7 | 21 | No chage |
| Example 78 | SUS430 | Cr | 10.0 | Ag—10 wt % Au | 20.0 | 7 | 21 | No chage |
| Example 79 | Kovar | Cr | 10.0 | Ag—10 wt % Au | 20.0 | 7 | 21 | No chage |
| Example 80 | Permalloy | Cr | 10.0 | Ag—10 wt % Au | 20.0 | 7 | 21 | No chage |
| Example 81 | Hastelloy | Cr | 10.0 | Ag—10 wt % Au | 20.0 | 7 | 21 | No chage |
| Example 82 | Invar | Cr | 10.0 | Ag—10 wt % Au | 20.0 | 7 | 21 | No chage |
| Example 83 | Inconel | Cr | 10.0 | Ag—10 wt % Au | 20.0 | 7 | 23 | No chage |

[Manufacture of the Metal Material with Electric Contact Layer]

As shown in table 1, in a case of each sample of examples 1 to 21 and comparative examples 1 to 6, a plate material having a plate thickness of t=0.1 mm made of SUS430 (stainless steel containing 16.00 to 18.00 wt % of Cr, 1.00 wt % or less of Mn, 0.75 wt % or less of Si, 0.12 wt % or less of C, 0.040 wt % or less of P, and 0.030 wt % or less of S) defined by JIS G4305 was used as the metal base made of metal mainly containing Cr.

Also, as shown in table 2, table 3, and table 4, in a case of each sample of examples 22 to 83, plate materials made of SUS304 (stainless steel containing 18.00 to 20.00 wt % of Cr, 8.00 to 10.50 wt % of Ni, 2.00 wt % or less of Mn, 1.00% wt or less of Si, 0.08 wt % or less of C, 0.045 wt % or less of P, 0.030 wt % or less of S) defined by JIS G4305, SUS316 (stainless steel containing 16.00 to 18.00 wt % of Cr, 10.00 to 14.00 wt % of Ni, 2.00 to 3.00 wt % of Mo, 2.00 wt % or less of Mn, 1.00 wt % or less of Si, 0.08 wt % or less of C, 0.045 WT % or less of P, 0.030 wt % or less of S) defined by JIS G4305, Kovar (Fe—Ni alloy, by Nilaco Corporation: Product Number (PN)633321), 78-Permalloy(Ni—Fe alloy, by Nilaco Corporation: PN783322), Invar(Fe—Ni—Co alloy, by Nilaco Corporation: PN623323), Hastelloy C276(Ni—Mo alloy, by Nilaco Corporation: PN583321), Inconel 600(Ni—Fe—Cr alloy, by Nilaco Corporation: PN603290), and Nichrome (Ni—Cr alloy, by Nilaco Corporation: PN693333), was used as the metal base made of metal containing Cr, unlike the aforementioned SUS430.

The plate thickness t of the metal base made of the aforementioned metal material is set at 0.1 mm. However, regarding the Nichrome, the metal base, with the plate thickness t set at 0.12 mm, was used for the convenience of preparing the material.

Then, the adhesive layer and the electric contact layer were continuously formed on the surface of the metal base in this order, so as to have material kinds (metal kinds) and thickness as shown in table 1 to table 4, in the same chamber by sputtering.

Such a film deposition process by sputtering was performed specifically by using an RF magnetron sputtering apparatus (by ULVAC Corporation, type: SH-350). Ar gas was used as an atmosphere during film deposition in the chamber, and the pressure was set at 7 Pa. An output of the RF magnetron was suitably adjusted, corresponding to the kind of the metal. The thickness was controlled for each kind of the metal to be deposited, by adjusting a film deposition time, based on an average film deposition speed of each kind of metal measured in advance. In these examples, the same film deposition process was applied to both sides (both sides of front and back) of the plate material, being the metal base.

Further specific description will be given for the material kind of the adhesive layer and the electric contact layer. In each sample of examples 1 to 21 shown in table 1, the adhesive layer contains pure Cr, and the electric contact layer contains any one of each kind of noble metal such as Au, Pt, Ru, Ir, Rh, Ag, and Pd. In each sample of comparative examples 1 to 6, the adhesive layer contains pure Cr, and the electric contact layer contains Au or Pt.

Also, in each sample of examples 22 to 35 shown in table 2, the adhesive layer contains pure Cr, and the electric contact layer contains Au.

In addition, in each sample of examples 36 to 51 shown in table 3, the adhesive layer contains Cr-16 wt % Ni, and the electric contact layer contains Au, and in each sample of examples 52 to 59, the adhesive layer contains Cr-16 wt % Co, and the electric contact layer contains Au.

Further, in each sample of examples 60 to 83 shown in table 4, the adhesive layer contains pure Cr, and the electric contact layer contains any one of each kind of the alloy of noble metal such as Pd-10 wt % Au, Ag-10 wt % Pd, Ag-10 wt % Au.

### [Manufacture of Sample as a Molded Product]

The molded product 20 with a corrugated plate structure part 21 formed therein, was manufactured in a center part of a square metal material with electric contact layer as shown in FIG. 2A, by applying press-molding work using a die having a corrugated shape, to a square and thin plate-shaped metal material with electric contact layer according to the examples and the comparative examples of the present invention.

As shown in FIG. 2B, being an expanded sectional view taken along the line B-B of FIG. 2A, the corrugated plate structure part 21 of the molded product 20 has a sectional shape in which trapezoidal tops (projections or ribs) 21a and bottoms (recesses or grooves) 21b are alternately formed. A length (length in a direction vertical to a paper surface of FIG. 2B) of the tops (projections or ribs) 21a or the bottoms (recesses or grooves) 21b of the corrugated plate structure part 21 was set at 52 mm. Pitch W between adjacent tops 21a (or between adjacent bottoms 21b) of the corrugated plate structure part 21 was set at 2.9 mm, and 17 tops (projections) 21a and bottoms (recesses) 21b in total were formed alternately. In addition, depth h (difference in high and low between the tops 21a and bottoms 21b) of the corrugated plate structure part 21 was set at 0.6 mm. “t” indicates the plate thickness of the molded product 20.

Note that the molded product 20 is a sample manufactured by assuming a metal separator for a fuel cell, and the grooves (bottoms or recesses) of the corrugated structure part 21 serve as a flow passage grooves for flowing a reaction gas (fuel gas such as hydrogen gas and oxidant gas such as air) of the fuel cell. In addition, holes 22 used in manifold holes for supplying/discharging the reaction gas to each cell of the laminated fuel cell or a hole for a member for fastening the laminated fuel cell are formed on an outer peripheral part of the corrugated plate structure part 21 of the molded product 20.

### [Environmental Test]

In an environmental test, a solution obtained by adding 1200 ppm of sodium chloride to a solution adjusted to pH2 by sulfuric acid and pure water was prepared, and each sample was immersed into this solution for 24 hours at a room temperature of 25° C. Note that each end face of the sample was sealed by a plastic masking tape and thereafter this sample was immersed into the solution, because coating treatment was not applied to an end face of each sample, with the metal base 1 in an exposed state.

### [Measurement of Contact Resistance]

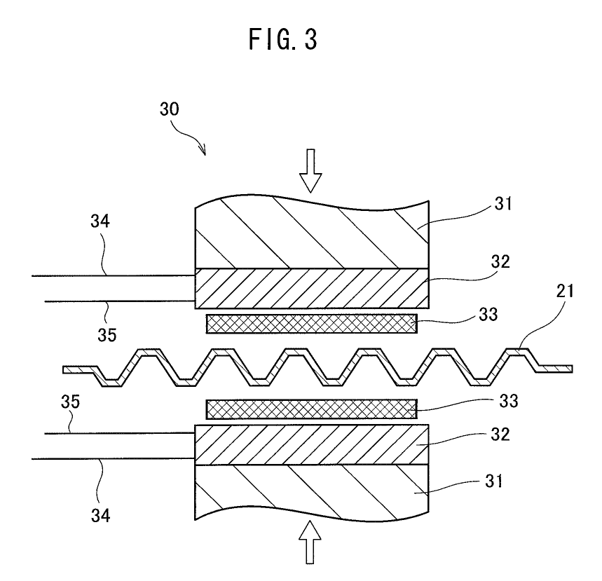

In a measurement of the contact resistance, as shown in FIG. 3, blocks 31, 31 made of Cu(copper), with an Au-plated electrode 32 formed on each facing surface of the blocks 31, 31, were used. The corrugated plate structure part 21 of the molded product 20, being the sample, was sandwiched between electrodes 32, 32 of the blocks 31, 31, via carbon paper 33 placed on upper and lower parts of the corrugated structure part 21 respectively, and weight (10 kg/cm²) was added thereto by a hydraulic press machine. Then, electric resistance values (unit:mQ) of the corrugated plate structure part 21 and two sheets of carbon paper placed on both sides of the corrugated plate structure part 21 were measured by an measurement apparatus of a four terminal measurement system (by ADEX CORPORATION. type:AX-125A), with the corrugated plate structure part 21 sandwiched between the electrodes 32, 32 by adding weight thereto. As shown in FIG. 3, a lead 34 for measuring current and a lead 35 for measuring voltage were connected to the electrodes 32, 32, respectively. A square (2 cm×2 cm=4 cm²) carbon paper (by TORAY CORPORATION: PN TGP-H-060) was used as the carbon paper 33. At this time, an occupation ratio λ of a contact surface between the electrode 32 and the corrugated plate structure part 21 was set at 0.5. Then, a value obtained by normalizing this electric resistance value by a surface area 4 cm² of the carbon paper 33 (namely a value obtained by multiplying this electric resistance value by four) was set as the contact resistance (unit: mΩ·cm²) of each sample.

### [Evaluation Method]

In an evaluation method of the contact resistance, the contact resistance of each sample was measured before and after the aforementioned environmental test, and whether or not contact resistance characteristics of each sample were adapted to a prescribed reference was evaluated, based on the value of the contact resistance particularly after the environmental test was conducted and a change of the contact resistance before/after the environmental test was conducted. In this example, a contact resistance value 25 mΩ·cm² was used as an evaluation reference value of the contact resistance characteristics, then the sample with the contact resistance set at 25 mΩ·cm² or less after the environmental test was evaluated as appropriate, and the sample with the contact resistance exceeding 25 mΩ·cm² was evaluated as inappropriate.

Also, in an evaluation method of the durability, a surface state of each sample was observed after the environmental test was conducted, and based on an occurrence of deterioration and breakage such as peel-off of the electric contact layer, whether or not the durability of each sample (and mechanical work adequacy, being possibility of the press-molding work) was adapted to a prescribed reference was confirmed.

### [Evaluation Result]

As shown in table 1, each sample of examples 1 to 21 was set, so that the metal base 1 was SUS430, the adhesive layer 2 contained pure Cr, and the electric contact layer 3 contained each kind of the noble metal such as Au, Pt, Ru, Ir, Rh, Ag, and Pd, and the thickness of the adhesive layer 2 was set in an adequate range (5 nm to 200 nm) specified in the aforementioned embodiment and the thickness of the electric contact layer 3 was set in an adequate range (1 nm to 20 nm) specified in the aforementioned embodiment. In each sample of the examples 1 to 21, the result showed 25 mΩ·cm² or less as the contact resistance value after the environmental test was conducted, thus allowing no deterioration or breakage such as peel-off to occur on the surface, and the sample was adapted to the evaluation reference.

Meanwhile, in a case of the sample of a comparative example 1 with no adhesive layer 2, although no surface peel-off, etc, was generated, the contact resistance after the environmental test was conducted was 32 mΩ·cm² exceeding 25 mΩ·cm², being the evaluation reference value, and the sample was evaluated as inappropriate.

In a case of the sample of a comparative example 2, with the thickness of the electric contact layer 3 containing Au set at 0.5 nm which is a value smaller than the adequate range (1 nm to 20 nm) as described in the aforementioned embodiment, the surface peel-off was not generated, but the contact resistance was 30 mΩ·cm² after the environmental test was conducted, and this sample was evaluated as inappropriate in terms of the contact resistance characteristics.

In a case of the sample of a comparative example 3, with the thickness of the electric contact layer 3 containing Au set at 25.0 nm which is a value larger than the adequate range (1 nm to 20 nm) as described in the aforementioned embodiment, the surface peel-off was not generated, but the contact resistance was 30 mΩ·cm² after the environmental test was conducted, and this sample was evaluated as inappropriate in terms of the contact resistance characteristics.

In a case of the sample of a comparative example 4, with the thickness of the adhesive layer 2 set at 250 nm which is a value larger than the adequate range (5 nm to 200 nm) as described in the aforementioned embodiment, the contact resistance was 44 mΩ·cm² after the environmental test was conducted, which was the value tremendously exceeding the evaluation reference value, and also the surface peel-off was generated, then this sample was evaluated as inappropriate in terms of both the contact resistance characteristics and durability.

Also, in a case of the sample of a comparative example 5, with the electric contact layer 3 made of Pt instead of Au, and the thickness of this electric contact layer 3 set at 0.5 nm which is the value smaller than the adequate range (1 nm to 20 nm) as described in the aforementioned embodiment, the surface peel-off was not generated similarly to the case of the comparative example 2, but the contact resistance was 30 mΩ·cm² after the environmental test was conducted, and this sample was evaluated as inappropriate in terms of the contact resistance characteristics.

Also, in a case of the sample of a comparative example 6, with the electric contact layer 3 made of Pt instead of Au, and the thickness of this electric contact layer 3 set at 25.0 nm which is the value larger than the adequate range (1 nm to 20 nm) as described in the aforementioned embodiment, the surface peel-off was not generated, but the contact resistance was 35 mΩ·cm² after the environmental test was conducted, and this sample was evaluated as inappropriate in terms of the contact resistance characteristics.

Then, as shown in table 2, table 3, and table 4, in a case of each sample of examples 22 to 83, the metal base 1 was made of each kind of metal material different from SUS430.

In a case of each sample (table 2) of examples 22 to 35, the adhesive layer 2 was made of pure Cr and the electric contact layer 3 was made of Au, and the thickness of the adhesive layer 2 was set in the adequate range (5 nm to 200 nm) as described in the aforementioned embodiment and the thickness of the electric contact layer 3 was set in the adequate range (1 nm to 20 nm) as described in the aforementioned embodiment. The result showed that the contact resistance was 25 mΩ·cm² or less after the environmental test was conducted and the deterioration or breakage such as peel-off was not generated on the surface, and it was confirmed that these samples were evaluated as being adapted to the evaluation reference.

Also, in a case of each sample (table 3) of examples 36 to 59, with the adhesive layer 2 made of Cr-16 wt % Ni or Cr-16 wt % Co, and the electric contact layer 3 made of Au, and the thickness of the adhesive layer 2 set at a value in an adequate range (5 nm to 200 nm) as described in the aforementioned embodiment and the thickness of the electric contact layer 3 set in a value in an adequate range (1 nm to 20 nm) as described in the aforementioned embodiment, the contact resistance was 25 mΩ·cm² or less after the environmental test was conducted, and the deterioration or breakage such as peel-off was not generated on the surface, and it was confirmed that this sample was evaluated as being adapted to the evaluation reference.

Further, in a case of each sample (table 4) of examples 60 to 83, with the adhesive layer 2 made of pure Cr, and the electric contact layer 3 made of each kind of the alloy of the noble metal, and the thickness of the adhesive layer 2 set in a value in an adequate range (5 nm to 200 nm) as described in the aforementioned embodiment and also the thickness of the electric contact layer 3 set in a value in an adequate range (1 nm to 20 nm) as described in the aforementioned embodiment, the contact resistance was 25 mΩ·cm² or less after the environmental test was conducted, and the deterioration or breakage such as peel-off was not generated on the surface, and it was confirmed that this sample was evaluated as being adapted to the evaluation reference.

In addition, when the contact resistance of each sample in a stage before the environmental test was conducted was compared and examined, which was shown by “initial value”, all examples 1 to 83 show values under 10 mΩ·cm². However, comparative examples 2 and 5 show 12 mΩ·cm², which was the value exceeding 10 mΩ·cm², and in this point also, it is confirmed that the metal material with electric contact layer according to the example of the present invention has excellent characteristics.

Thus, according to this example, by forming the adhesive layer made of metal mainly containing Cr and having a thickness of 5 nm or more and 200 nm or less on the surface of the metal base made of the metal containing chromium, and further forming thereon the electric contact layer made of the noble metal or the alloy of the noble metal and having a thickness of 1 nm or more and 20 nm or less, it was verified that both of the reduction of the use amount of the noble metal, being a forming material of the electric contact layer; and press-molding applied to the metal material with electric contact layer without posing a problem such as peel-off of the electric contact layer and deterioration of the durability, could be surely achieved at a high level.

Note that in an application of the present invention to an actual product, etc, it is a matter of course that a shape of the product by press-molding is not limited to the aforementioned corrugated shape. The product can also be molded into various shapes other than the corrugated shape.

The electric contact layer 3 needs not to be necessarily formed on both sides of the front and back of the metal base 1, and it is a matter of course that the electric contact layer 3 can also be formed only on one side, or can be formed only at a prescribed position on the surface of the metal base 1, or can be formed into a prescribed pattern shape.

The aforementioned example describes a case that the adhesive layer 2 contains pure Cr, Cr-16 wt % Ni, and Cr-16 wt % Co. However, selection and concentration of the material kind of different kind of metal added to Cr is not limited thereto.

The aforementioned example describes a case that the electric contact layer 3 is made of Pd-10 wt % Au, Ag-10 wt % Pd, and Ag-10 wt % Au, being alloys of the noble metal, other than each kind of noble metal. However, the selection of combination of the material kind of the alloys of the noble metal used as the forming material of the electric contact layer 3 and content concentration of each element are not limited thereto.

What is claimed is:

1. A metal material with electric contact layer, comprising:
a metal base made of metal containing chromium;
an adhesive layer formed on a surface of the metal base, made of metal mainly containing chromium, and having a thickness of 5 nm or more and 200 nm or less; and
an electric contact layer formed on the surface of the adhesive layer, made of noble metal or an alloy of the noble metal, and having a thickness of 1 nm or more and 20 nm or less.

2. The metal material with electric contact layer according to claim 1, wherein the electric contact layer is made of the noble metal selected from any one of gold, platinum, rhodium, ruthenium, iridium, silver, and palladium, or the alloy of the noble metal containing at least one kind of them.

3. The metal material with electric contact layer according to claim 1, wherein the adhesive layer is made of metal mainly containing chromium and further containing nickel or cobalt.

4. The metal material with electric contact layer according to claim 1, wherein the metal base further contains iron.

5. The metal material with electric contact layer according to claim 1, wherein the metal base is a stainless steel.

6. The metal material with electric contact layer according to claim 1, wherein the metal base is a stainless steel containing 18.00 to 20.00 wt % of Cr, 8.00 to 10.50 wt % of Ni, 2.00 wt % or less of Mn, 1.00 wt % or less of Si, 0.08 wt % or less of C, 0.045 wt % or less of P, and 0.030 wt % or less of S.

7. The metal material with electric contact layer according to claim 1, wherein the metal base is a stainless steel containing 16.00 to 18.00 wt % of Cr, 1.00 wt % or less of Mn, 0.75 wt % or less of Si, 0.12 wt % or less of C, 0.040 wt % or less of P, and 0.030 wt % or less of S.

8. The metal material with electric contact layer according to claim 1, wherein the metal base is a stainless steel containing 16.00 to 18.00 wt % of Cr, 10.00 to 14.00 wt % of Ni, 2.00 to 3.00 wt % of Mo, 2.00 wt % or less of Mn, 1.00 wt % or less of Si, 0.08% or less of C, 0.045 wt % or less of P, and 0.030 wt % or less of S.

9. The metal material with electric contact layer according to claim 1, wherein the metal base is any one of Kovar (trademark), Permalloy, Hastelloy (trademark), Invar, Inconel (trademark), and Nichrome.

10. A manufacturing method of a metal material with electric contact layer, comprising the steps of:
forming an adhesive layer made of metal mainly containing chromium, on a surface of a metal base made of metal containing chromium, by a vapor phase method in a chamber, so as to have a thickness of 5 nm or more and 200 nm or less; and
forming an electric contact layer made of noble metal or an alloy of the noble metal, on the surface of the adhesive layer, subsequent to formation of the adhesive layer in the chamber, by the vapor phase method so as to have a thickness of 1 nm or more and 20 nm or less.

11. The manufacturing method of the metal material with electric contact layer according to claim 10, wherein the electric contact layer is made of the noble metal selected from any one of gold, platinum, rhodium, ruthenium, iridium, silver, and palladium, or the alloy of the noble metal containing at least one kind of them.

12. The manufacturing method of the metal material with electric contact layer according to claim 10, wherein the adhesive layer is made of metal mainly containing chromium and further containing nickel or cobalt.

13. The manufacturing method of the metal material with electric contact layer according to claim 10, wherein the metal base further contains iron.

14. The manufacturing method of the metal material with electric contact layer according to claim 10, wherein the metal base is a stainless steel.

15. The manufacturing method of the metal material with electric contact layer according to claim 10, wherein the metal base is a stainless steel containing 18.00 to 20.00 wt % of Cr, 8.00 to 10.50 wt % of Ni, 2.00 wt % or less of Mn, 1.00 wt % or less of Si, 0.08 wt % or less of C, 0.045 wt % or less of P, and 0.030 wt % or less of S.

16. The manufacturing method of the metal material with electric contact layer according to claim 10, wherein the metal base is a stainless steel containing 16.00 to 18.00 wt % of Cr, 1.00 wt % or less of Mn, 0.75 wt % or less of Si, 0.12 wt % or less of C, 0.040 wt % or less of P, and 0.030 wt % or less of S.

17. The manufacturing method of the metal material with electric contact layer according to claim 10, wherein the metal base is a stainless steel containing 16.00 to 18.00 wt % of Cr, 10.00 to 14.00 wt % of Ni, 2.00 to 3.00 wt % of Mo, 2.00 wt % or less of Mn, 1.00 wt % or less of Si, 0.08 wt % or less of C, 0.045 wt % or less of P, and 0.030 wt % or less of S.

18. The manufacturing method of the metal material with electric contact layer according to claim 10, wherein the metal base is any one of Kovar (trademark), Permalloy, Hastelloy (trademark), Invar, Inconel (trademark), and Nichrome.

19. The manufacturing method of the metal material with electric contact layer according to claim 10, wherein the vapor phase method is any one of sputtering, vacuum deposition, ion beam deposition, ion plating, and chemical vapor deposition.

20. The manufacturing method of the metal material with electric contact layer according to claim 10, wherein oxidation process or anodizing is performed after formation of the electric contact layer.
